(19) United States
(12) Patent Application Publication
(10) Pub. No.: US 2025/0366312 A1
(43) Pub. Date: Nov. 27, 2025

(54) DISPLAY DEVICE, METHOD OF MANUFACTURING DISPLAY DEVICE, AND ELECTRONIC DEVICE COMPRISING DISPLAY DEVICE

(71) Applicant: Samsung Display Co., LTD., Yongin-si (KR)

(72) Inventors: Keun Woo KIM, Yongin-si (KR); Hyoung Do KIM, Yongin-si (KR); Joon Seok PARK, Yongin-si (KR); Sun Hee LEE, Yongin-si (KR); Cheol Gon LEE, Yongin-si (KR); Mu Kyung JEON, Yongin-si (KR); Hye Lim CHOI, Yongin-si (KR)

(21) Appl. No.: 18/979,838

(22) Filed: Dec. 13, 2024

(30) Foreign Application Priority Data
May 24, 2024 (KR) 10-2024-0067732

(51) Int. Cl. H10K 59/121; H10D 86/01; H10D 86/40; H10D 86/60; H10K 59/12

(52) U.S. Cl. CPC H10K 59/1213; H10D 86/0229; H10D 86/423; H10D 86/60; H10K 59/1201

(57) ABSTRACT

A display device includes a pixel circuit layer including a base layer, a first transistor on the base layer and a second transistor on the base layer. The first transistor includes a first active layer, a first upper gate conductive layer on the first active layer, and an intermediate conductive structure spaced further from the base layer than the first upper gate conductive layer is, and the second transistor includes a second active layer and a second upper gate conductive layer on the second active layer, and a light emitting element on the pixel circuit layer. The first active layer includes a polysilicon material, and the second active layer includes an oxide semiconductor. The intermediate conductive structure is in a same layer as the second upper gate conductive layer and is connected to the first active layer or the first upper gate conductive layer through a contact structure.

This application claims priority to Korean Patent Application No. 10-2024-0067732, filed on May 24, 2024, and all the benefits accruing therefrom under 35 U.S.C. § 119, the content of which in its entirety is herein incorporated by reference.

### BACKGROUND

### 1. Field

Embodiments of the disclosure relate to a display device, a method of manufacturing the display device, and an electronic device comprising the display device.

### 2. Description of the Related Art

Recently, as interest in information display is increased, research and development on a display device is continuously being conducted.

The display device includes a structure in which a plurality of layers are patterned. For example, the display device may include a contact structure that electrically connects layers in different layers to each other. In order to form the contact structure, two or more manufacturing processes may be performed.

### SUMMARY

When two or more manufacturing processes to form a plurality patterned layers are progressed, each of the manufacturing processes may affect previously patterned layers. In order to improve operation reliability of the display device, it may be desired to reduce an influence between the manufacturing processes.

Embodiments of the disclosure provide a display device, a method of manufacturing the display device, and an electronic device comprising the display device in which reliability of electrical signal in the display device is considered.

Embodiments of the disclosure provide a display device, a method of manufacturing the display device, and an electronic device comprising the display device in which a manufacturing process may be simplified.

Embodiments of the disclosure provide a display device, a method of manufacturing the display device, and an electronic device comprising the display device in which an element characteristic of circuit elements for driving a pixel may be appropriately controlled.

Embodiments of the disclosure provide a display device, a method of manufacturing the display device, and an electronic device comprising the display device in which a risk that an element characteristic for semiconductor structures forming the display device is changed may be reduced during a manufacturing process.

According to an embodiment of the disclosure, a display device includes a pixel circuit layer including a base layer, a first transistor disposed on the base layer and a second transistor disposed on the base layer, where the first transistor includes a first active layer, a first upper gate conductive layer disposed on the first active layer, and an intermediate conductive structure spaced from the base layer than the first upper gate conductive layer, and the second transistor includes a second active layer and a second upper gate conductive layer disposed on the second active layer, and a light emitting element disposed on the pixel circuit layer. In such an embodiment, the first active layer includes a polysilicon material and may be disposed in a polysilicon semiconductor area, and the second active layer includes an oxide semiconductor and may be disposed in an oxide semiconductor area. In such an embodiment, the intermediate conductive structure is disposed in a same layer as the second upper gate conductive layer and is electrically connected to at least one selected from the first active layer and the first upper gate conductive layer through a contact structure.

According to an embodiment, the first transistor may include a driving transistor. In such an embodiment, the second transistor may include a switching transistor. In such an embodiment, the second active layer may be further spaced apart from the base layer that the first active layer is.

According to an embodiment, the first active layer may include at least one selected from low-temperature polycrystalline silicon (LTPS), hybrid oxide polycrystalline silicon (HOP), and hybrid oxide low-temperature polycrystalline silicon (HOL). In such an embodiment, the second active layer may include at least one selected from indium gallium zinc oxide (IGZO) and indium tin gallium zinc oxide (ITGZO).

According to an embodiment, the first transistor may further include an additional gate conductive layer overlapping the first upper gate conductive layer in a plan view. In such an embodiment, the second transistor may further include a lower gate conductive layer disposed between the second active layer and the base layer. In such an embodiment, the additional gate conductive layer and the lower gate conductive layer may be disposed in a same layer as each other.

According to an embodiment, the first transistor may further include first transistor electrodes disposed on the intermediate conductive structure. In such an embodiment, the second transistor may further include second transistor electrodes disposed in a same layer as the first transistor electrodes.

In such an embodiment, the contact structure may include a conductive material different from a material of the first transistor electrodes.

According to an embodiment, the intermediate conductive structure may electrically connect the first transistor electrodes and the first active layer to each other.

According to an embodiment, the intermediate conductive structure may be electrically connected to the first upper gate conductive layer.

According to an embodiment, a portion of the intermediate conductive structure may be electrically connected to the first active layer. In such an embodiment, another portion of the intermediate conductive structure may be electrically connected to the first upper gate conductive layer.

According to an embodiment of the disclosure, a method of manufacturing a display device includes manufacturing a pixel circuit layer, and manufacturing a light emitting element layer disposed on the pixel circuit layer. In such an embodiment, the manufacturing the pixel circuit layer includes patterning a first active layer in a polysilicon semiconductor area on a base layer, patterning a first upper gate conductive layer overlapping the first active layer, patterning a second active layer in an oxide semiconductor area on the base layer, forming a first hole exposing at least one selected from the first upper gate conductive layer and the first active layer, performing an annealing process, and patterning a second upper gate conductive layer and an intermediate conductive structure, after the performing the annealing process.

According to an embodiment, the method may further include patterning an additional gate conductive layer overlapping the first upper gate conductive layer in the polysilicon semiconductor area and a lower gate conductive layer in the oxide semiconductor area. In such an embodiment, the patterning the second active layer may include forming the second active layer to overlap the lower gate conductive layer.

According to an embodiment, the performing the annealing process may include releasing hydrogen from the first active layer and the second active layer.

According to an embodiment, the method may further include forming a gate insulating layer covering the second active layer, after the patterning the second active layer. In such an embodiment, in the performing the annealing process, the gate insulating layer may cover the second active layer. In such an embodiment, the gate insulating layer may include silicon oxide (SixOy) and does not include silicon nitride (SixNy).

According to an embodiment, the method may further include forming an interlayer insulating layer on the second upper gate conductive layer and the intermediate conductive structure. In such an embodiment, the interlayer insulating layer may include silicon nitride (SixNy).

According to an embodiment, the method may further include forming a second hole exposing the intermediate conductive structure, and forming a third hole exposing the second active layer.

According to an embodiment, the method may further include patterning first transistor electrodes and second transistor electrodes. In such an embodiment, the first transistor electrodes may be formed in the second hole and electrically connected to the intermediate conductive structure, and the second transistor electrodes may be formed in the third hole and electrically connected to the second active layer.

According to an embodiment, the first transistor electrodes and the intermediate conductive structure may include different conductive materials.

According to an embodiment, the forming the first hole may include exposing the first upper gate conductive layer without exposing the first active layer.

According to an embodiment, the patterning the first upper gate conductive layer may include forming an opening through the first upper gate conductive layer. In such an embodiment, in the forming the first hole, the first hole may passthrough the opening.

According to an embodiment, the forming the first hole may include exposing the first active layer, and exposing the first upper gate conductive layer.

According to an embodiment, the patterning the intermediate conductive structure may include electrically connecting a portion of the intermediate conductive structure to the first active layer, and electrically connecting another portion of the intermediate conductive structure to the first upper gate conductive layer.

According to an embodiment of the disclosure, an electronic device may comprise: a processor configured to provide input image data; a display device configured to display an image based on the input image data, the display device including sub-pixel areas; and a power supply configured to supply power to the display device. The display device may include a pixel circuit layer including a base layer, a first transistor disposed on the base layer and a second transistor disposed on the base layer, where the first transistor includes a first active layer, a first upper gate conductive layer disposed on the first active layer, and an intermediate conductive structure spaced from the base layer than the first upper gate conductive layer, and the second transistor includes a second active layer and a second upper gate conductive layer disposed on the second active layer, and a light emitting element disposed on the pixel circuit layer. In such an embodiment, the first active layer includes a polysilicon material and may be disposed in a polysilicon semiconductor area, and the second active layer includes an oxide semiconductor and may be disposed in an oxide semiconductor area. In such an embodiment, the intermediate conductive structure is disposed in a same layer as the second upper gate conductive layer and is electrically connected to at least one selected from the first active layer and the first upper gate conductive layer through a contact structure.

According to an embodiment of the disclosure, a display device, a method of manufacturing the display device, and an electronic device comprising the display device in which reliability for an electrical signal in the display device is considered may be provided.

According to an embodiment of the disclosure, a display device, a method of manufacturing the display device, and an electronic device comprising the display device in which a manufacturing process may be simplified may be provided.

According to an embodiment of the disclosure, a display device, a method of manufacturing the display device, and an electronic device comprising the display device in which an element characteristic of circuit elements for driving a pixel may be appropriately controlled may be provided.

According to an embodiment of the disclosure, a display device, a method of manufacturing the display device, and an electronic device comprising the display device in which a risk that an element characteristic for semiconductor structures forming the display device is changed may be reduced during a manufacturing process may be provided.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a schematic plan view illustrating a display device according to an embodiment;

FIG. 2 is a schematic cross-sectional view illustrating a display device according to an embodiment;

FIGS. 3 to 5 are schematic cross-sectional views illustrating a display device according to embodiments;

FIG. 6 is a schematic flowchart illustrating a method of manufacturing a display device according to an embodiment; and

FIGS. 7 to 29 are schematic cross-sectional views for each process step illustrating a method of manufacturing a display device according to an embodiment.

FIG. 30 is a schematic block diagram illustrating an electronic device including a display device in accordance with an embodiment.

FIG. 31 is a schematic diagram illustrating an example where the electronic device of FIG. 30 is implemented as a smartphone.

FIG. 32 is a schematic diagram illustrating an example where the electronic device of FIG. 30 is implemented as a tablet computer.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device, a method of manufacturing the display device, and an electronic device comprising the display device according to embodiments will be described with reference to the accompanying drawings.

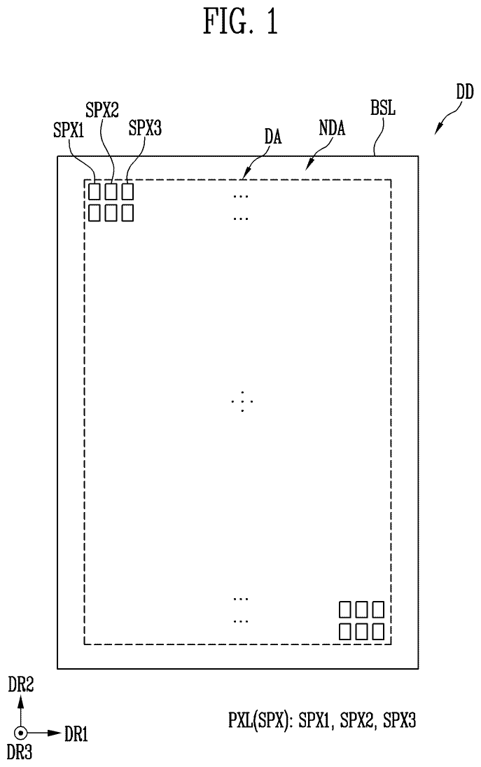

FIG. 1 is a schematic plan view illustrating a display device according to an embodiment.

Referring to FIG. 1, an embodiment of the display device DD may include a base layer BSL and a pixel PXL disposed on the base layer BSL. Although not shown in the drawing, the display device DD may further include a driving circuit unit (for example, a scan driver and a data driver), lines, and pads for driving the pixel PXL.

The display device DD (or the base layer BSL) may include a display area DA and a non-display area NDA. The non-display area NDA may mean an area other than the display area DA. The non-display area NDA may surround at least a portion of the display area DA.

The base layer BSL may form a base surface of the display device DD. The base layer BSL may be a rigid or flexible substrate or film. In an embodiment, for example, the base layer BSL may include a glass material. Alternatively, the base layer BSL may include a silicon material. Alternatively, the base layer BSL may include polyimide. In an embodiment, for example, the base layer BSL may include a first polyimide layer, an inorganic barrier layer disposed on the first polyimide layer and including an inorganic material, and a second polyimide layer disposed on the inorganic barrier layer. However, the disclosure is not limited thereto.

The display area DA may mean an area where the pixel PXL is disposed. The non-display area NDA may mean an area where the pixel PXL is not disposed. The driving circuit unit, the line, and the pads connected to the pixel PXL of the display area DA may be disposed in the non-display area NDA.

According to an embodiment, the pixel PXL (or sub-pixels SPX) may be arranged in a stripe or PENTILE™ arrangement structure, but are not limited thereto, and various embodiments may be applied to the disclosure.

According to an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one selected from the first sub-pixel SPX1, the second sub-pixel SPX2, and the third sub-pixel SPX3 may form a pixel unit capable of emitting light of various colors.

Each of the first sub-pixel SPX1, the second sub-pixel SPX2, and the third sub-pixel SPX3 may emit light of a predetermined color.

In an embodiment, for example, the first sub-pixel SPX1 may be a red pixel that emits light of red (for example, first color), the second sub-pixel SPX2 may be a green pixel that emits light of green (for example, second color), and the third sub-pixel SPX3 may be a blue pixel that emits light of blue (for example, third color). The red pixel may provide light of a wavelength range of about 600 nanometers (nm) to about 750 nm. The green pixel may provide light of a wavelength band of about 480 nm to about 560 nm. The blue pixel may provide light of a wavelength range of about 370 nm to about 460 nm.

According to an embodiment, the number of second sub-pixels SPX2 may be greater than the number of first sub-pixels SPX1 and the number of third sub-pixels SPX3. However, the color, type, number, and/or the like of the first sub-pixel SPX1, the second sub-pixel SPX2, and the third sub-pixel SPX3 forming each pixel unit are/is not limited to a specific example.

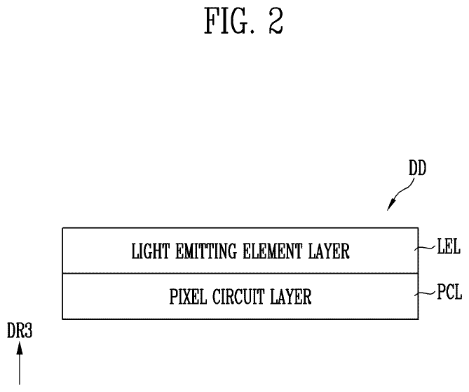

FIG. 2 is a schematic cross-sectional view illustrating a display device according to an embodiment.

Referring to FIG. 2, the display device DD may include a pixel circuit layer PCL and a light emitting element layer LEL.

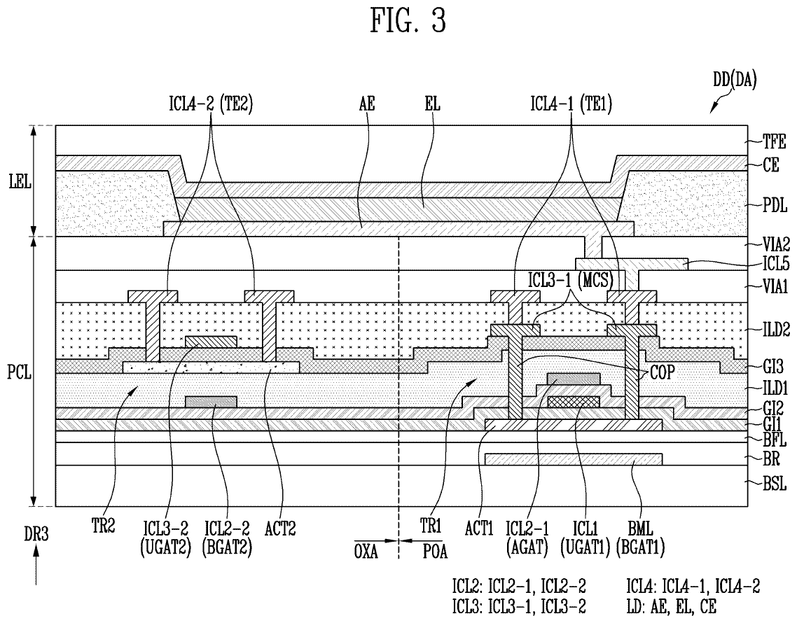

The pixel circuit layer PCL may include the base layer BSL. The pixel circuit layer PCL may be a layer including a pixel circuit. The pixel circuit layer PCL may be a backplane layer. The pixel circuit may be formed on the base layer BSL and may be configured to drive a light emitting element LD (refer to FIG. 3). The pixel circuit layer PCL may include conductive layers and insulating layers, and the conductive layers may form the pixel circuit. The pixel circuit may include circuit elements. The circuit elements may include a driving transistor and may include an additional transistor and capacitors. According to an embodiment, the pixel circuit layer PCL may include circuit elements, each including two or more different types of semiconductors, which will be described later in greater detail.

The light emitting element layer LEL may be disposed on the pixel circuit layer PCL. The light emitting element layer LEL may include the light emitting element LD. The light emitting element LD may be electrically connected to the pixel circuit. According to an embodiment, the light emitting element LD may include an organic light emitting diode (OLED) including an organic material. In an alternative embodiment, the light emitting element LD may include an inorganic light emitting diode including an inorganic material. However, the disclosure is not limited thereto.

Hereinafter, for convenience of description, embodiments in which the light emitting element LD is the OLED will be mainly described.

Hereinafter, with reference to FIGS. 3 to 5, a display device DD including a polysilicon semiconductor area POA and an oxide semiconductor area OXA according to an embodiment will be described.

FIGS. 3 to 5 are schematic cross-sectional views illustrating a display device according to embodiments.

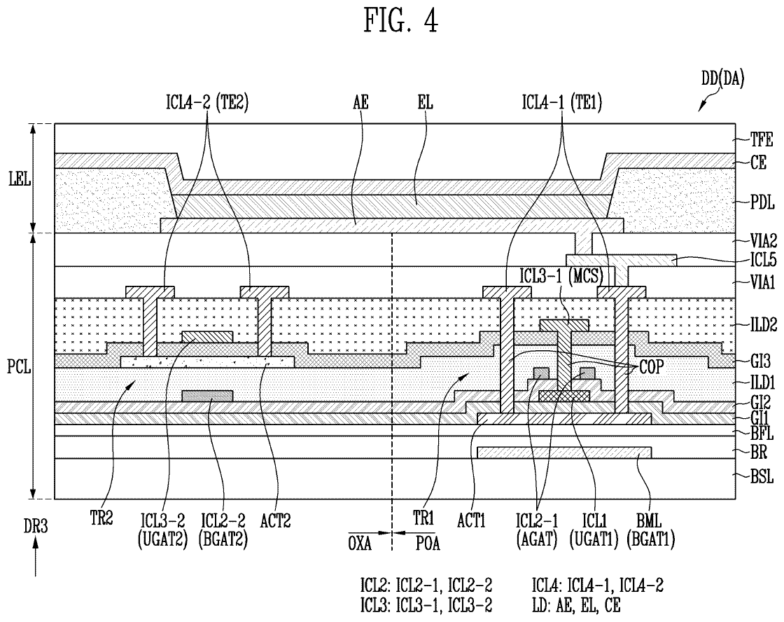

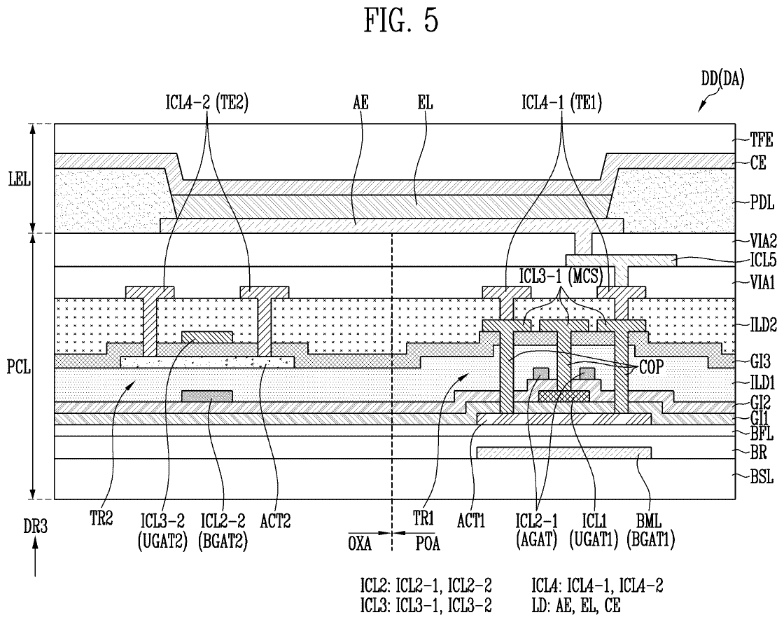

FIG. 3 schematically shows a display device DD according to an embodiment in the display area DA. FIG. 4 schematically shows a display device DD according to another embodiment in the display area DA. FIG. 5 schematically shows a display device DD according to another embodiment in the display area DA.

Referring to FIG. 3, in an embodiment, the display device DD may include the oxide semiconductor area OXA and the polysilicon semiconductor area POA.

According to an embodiment, the pixel circuit layer PCL may include circuit elements based on a semiconductor layer including two or more different semiconductor materials.

The polysilicon semiconductor area POA may be an area where a circuit element (for example, a first transistor TR1) including a first active layer ACT1 including a polysilicon semiconductor material is disposed.

The oxide semiconductor area OXA may be an area where a circuit element (for example, a second transistor TR2) including a second active layer ACT2 including an oxide semiconductor is disposed.

According to an embodiment, each of the first and second active layers ACT1 and ACT2 may form predetermined circuit element(s) based on an operation characteristic of the circuit elements.

In an embodiment, for example, the first transistor TR1 including the first active layer ACT1 may form a driving transistor of the pixel circuit. In such an embodiment, the second transistor TR2 including the second active layer ACT2 may form a switching transistor of the pixel circuit. In such an embodiment, based on an element characteristic desired for each of the driving transistor and the switching transistor, a semiconductor material of each of the transistors TR1 and TR2 may be determined, and thus an element characteristic desired for each of the driving transistor and the switching transistor may be relatively appropriately determined.

The first active layer ACT1 may be adjacent to the base layer BSL compared to the second active layer ACT2, that is, a distance between the first active layer ACT1 and the base layer BSL in a thickness direction of the base layer BSL is less than a distance between the second active layer ACT2 and the base layer BSL in the thickness direction of the base layer BSL. The first active layer ACT1 may be patterned in a process for forming thereof in a time period preceding a process for forming the second active layer ACT2.

In an embodiment, for example, the first active layer ACT1 may be formed below the second active layer ACT2, and the second active layer ACT2 may be formed above the first active layer ACT1.

According to an embodiment, the oxide semiconductor area OXA and the polysilicon semiconductor area POA may be spaced apart from each other.

However, the disclosure is not limited thereto. For example, in another embodiment, the oxide semiconductor area OXA and the polysilicon semiconductor area POA may partially overlap each other in a plan view or when viewed in the thickness direction of the base layer BSL.

According to an embodiment, the pixel circuit layer PCL including the polysilicon semiconductor area POA and the oxide semiconductor area OXA may include a plurality of conductive layers and a plurality of insulating layers.

According to an embodiment, the pixel circuit layer PCL may include the base layer BSL, a lower conductive layer BML, a barrier layer BR, a buffer layer BFL, the first active layer ACT1, a first gate insulating layer GI1, a first interlayer conductive layer ICL1, a second gate insulating layer GI2, a second interlayer conductive layer ICL2, a first interlayer insulating layer ILD1, the second active layer ACT2, a third gate insulating layer GI3, a third interlayer conductive layer ICL3, a second interlayer insulating layer ILD2, a fourth interlayer conductive layer ICL4, a first via layer VIA1, a fifth interlayer conductive layer ICL5, and a second via layer VIA2.

The lower conductive layer BML may be disposed on the base layer BSL. At least a portion of the lower conductive layer BML may be disposed in the polysilicon semiconductor area POA. The lower conductive layer BML may overlap the first active layer ACT1 in a plan view or when viewed in the thickness direction of the base layer BSL. The lower conductive layer BML may include at least one selected from various conductive materials. According to an embodiment, at least a portion of the lower conductive layer BML may form (or function as) a first lower gate electrode BGAT1 for the first transistor TR1. In an embodiment, for example, the first lower gate electrode BGAT1 may form a gate electrode portion of the first transistor TR1. However, the disclosure is not limited thereto.

The plane defined in this specification may be a direction extending in a first direction DR1 and a second direction DR2 and may be defined based on a plane where the base layer BSL is disposed. According to an embodiment, a third direction DR3 may be the thickness direction of the base layer BSL, and the third direction DR3 may be a light emission direction of the display device DD.

The barrier layer BR may cover the lower conductive layer BML and may be disposed on the base layer BSL. The barrier layer BR may be disposed across the polysilicon semiconductor area POA and the oxide semiconductor area OXA. The barrier layer BR may include an inorganic material including silicon oxide (SixOy). However, the disclosure is not limited thereto.

The buffer layer BFL may be disposed on the barrier layer BR. The buffer layer BFL may be disposed across the polysilicon semiconductor area POA and the oxide semiconductor area OXA. The buffer layer BFL may include an inorganic material including silicon oxide (SixOy) and silicon nitride (SixNy). However, the disclosure is not limited thereto.

The first active layer ACT1 may be disposed (for example, directly disposed) on the buffer layer BFL. The first active layer ACT1 may be disposed in the polysilicon semiconductor area POA. The first active layer ACT1 may include a material different from that of the second active layer ACT2. The first active layer ACT1 may include at least one selected from low-temperature polycrystalline silicon (LTPS), hybrid oxide polycrystalline silicon (HOP), and hybrid oxide low-temperature polycrystalline silicon (HOL).

The first gate insulating layer GI1 may cover the first active layer ACT1 and may be disposed on the buffer layer BFL. The first gate insulating layer GI1 may be disposed across the polysilicon semiconductor area POA and the oxide semiconductor area OXA. The first gate insulating layer GI1 may include an inorganic material including silicon oxide (SixOy). However, the disclosure is not limited thereto.

The first interlayer conductive layer ICL1 may be disposed on the first gate insulating layer GI1. At least a portion of the first interlayer conductive layer ICL1 may be disposed in the polysilicon semiconductor area POA. The first interlayer conductive layer ICL1 may include at least one selected from various conductive materials.

At least a portion of the first interlayer conductive layer ICL1 may form a first upper gate conductive layer UGAT1. The first upper gate conductive layer UGAT1 may overlap the first active layer ACT1 in a plan view or when viewed in the thickness direction of the base layer BSL (i.e., the third direction DR3). The first upper gate conductive layer UGAT1 may form the gate electrode portion of the first transistor TR1.

The second gate insulating layer GI2 may cover the first interlayer conductive layer ICL1 and may be disposed on the first gate insulating layer GI1. The second gate insulating layer GI2 may be disposed across the polysilicon semiconductor area POA and the oxide semiconductor area OXA. The second gate insulating layer GI2 may include an inorganic material including silicon nitride (SixNy). However, the disclosure is not limited thereto.

The second interlayer conductive layer ICL2 may be disposed on the second gate insulating layer GI2. The second interlayer conductive layer ICL2 may include a first second interlayer conductive layer ICL2-1 disposed in the polysilicon semiconductor area POA and a second second interlayer conductive layer ICL2-2 disposed in the oxide semiconductor area OXA. The second interlayer conductive layer ICL2 may include various conductive materials.

At least a portion of the first second interlayer conductive layer ICL2-1 may form an additional gate conductive layer AGAT. The additional gate conductive layer AGAT may overlap the first upper gate conductive layer UGAT1 in a plan view or when viewed in the thickness direction of the base layer BSL. The additional gate conductive layer AGAT may form the gate electrode portion of the first transistor TR1.

At least a portion of the second second interlayer conductive layer ICL2-2 may form a second lower gate conductive layer BGAT2. The second lower gate conductive layer BGAT2 may overlap the second active layer ACT2 in a plan view or when viewed in the thickness direction of the base layer BSL. The second lower gate conductive layer BGAT2 may form a gate electrode portion of the second transistor TR2.

According to an embodiment, the gate electrode portion of the second transistor TR2 based on an oxide semiconductor may be formed on and under the second active layer ACT2, respectively. In addition, the second lower gate conductive layer BGAT2 disposed under the second active layer ACT2 may be formed adjacent to a corresponding sub-pixel SPX (for example, light emitting element LD). In such an embodiment, a risk of a signal delay or the like of a gate signal for operating the second transistor TR2 may be reduced, and a resolution characteristic of the display device DD may be improved.

The first second interlayer conductive layer ICL2-1 and the second second interlayer conductive layer ICL2-2 may be patterned in a same process, may be disposed in (or directly on) a same layer, and may include a same conductive material.

The first interlayer insulating layer ILD1 may cover the second interlayer conductive layer ICL2 and may be disposed on the second gate insulating layer GI2. The first interlayer insulating layer ILD1 may be disposed across the polysilicon semiconductor area POA and the oxide semiconductor area OXA. According to an embodiment, the first interlayer insulating layer ILD1 may be a buffer layer for the second active layer ACT2. The first interlayer insulating layer ILD1 may include an inorganic material including silicon oxide (SixOy) and silicon nitride (SixNy). However, the disclosure is not limited thereto.

The second active layer ACT2 may be disposed (for example, directly disposed) on the first interlayer insulating layer ILD1. The second active layer ACT2 may be disposed in the oxide semiconductor area OXA. The second active layer ACT2 may include a material different from that of the first active layer ACT1. The second active layer ACT2 may include an oxide semiconductor. In an embodiment, for example, the second active layer ACT2 may include at least one selected from indium gallium zinc oxide (IGZO) and indium tin gallium zinc oxide (ITGZO). However, the disclosure is not limited thereto.

The third gate insulating layer GI3 may cover the second active layer ACT2 and may be disposed on the first interlayer insulating layer ILD1. The third gate insulating layer GI3 may be disposed across the polysilicon semiconductor area POA and the oxide semiconductor area OXA. The third gate insulating layer GI3 may include an inorganic material including silicon oxide (SixOy). However, the disclosure is not limited thereto.

The third interlayer conductive layer ICL3 may be disposed on the third gate insulating layer GI3. The third interlayer conductive layer ICL3 may include a first third interlayer conductive layer ICL3-1 disposed in the polysilicon semiconductor area POA and a second third interlayer conductive layer ICL3-2 disposed in the oxide semiconductor area OXA. The third interlayer conductive layer ICL3 may include at least one selected from various conductive materials.

At least a portion of the first third interlayer conductive layer ICL3-1 may form an intermediate conductive structure MCS. The intermediate conductive structure MCS may electrically connect first transistor electrodes TE1 and the first active layer ACT1. The intermediate conductive structure MCS may overlap the first active layer ACT1 in a plan view or when viewed in the thickness direction of the base layer BSL. The intermediate conductive structure MCS may be electrically connected to the first active layer ACT1 through a contact structure COP provided through insulating layers between the first active layer ACT1 and the intermediate conductive structure MCS. The intermediate conductive structure MCS and the contact structure COP may be formed in a same process (for example, deposition), may be disposed in (or directly on) a same layer, and may include a same conductive material.

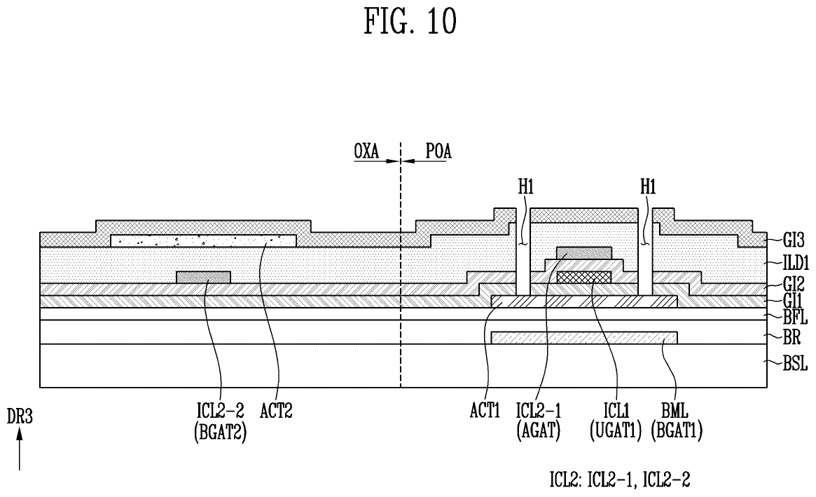

According to an embodiment, the contact structure COP may be a conductive structure manufactured as conductive materials that are filled after a first hole H1 (refer to FIG. 10) is formed in corresponding insulating layers. That is, in order to provide the contact structure COP, the first hole H1 may be formed in a previous process. The first hole H1 may function as a path for hydrogen to be released to an outside when an annealing process on the first active layer ACT1 including a polysilicon material is performed. That is, formation of the contact structure COP may mean that process a risk that may occur during an annealing process may be reduced, which will be described later in greater detail.

At least a portion of the second third interlayer conductive layer ICL3-2 may form a second upper gate conductive layer UGAT2. The second upper gate conductive layer UGAT2 may overlap the second active layer ACT2 in a plan view or when viewed in the thickness direction of the base layer BSL. The second upper gate conductive layer UGAT2 may form the gate electrode portion of the second transistor TR2.

The first third interlayer conductive layer ICL3-1 and the second third interlayer conductive layer ICL3-2 may be patterned in a same process, may be disposed in (or directly on) a same layer, and may include a same conductive material.

The second interlayer insulating layer ILD2 may cover the third interlayer conductive layer ICL3 and may be disposed on the third gate insulating layer GI3. The second interlayer insulating layer ILD2 may be disposed across the polysilicon semiconductor area POA and the oxide semiconductor area OXA. The second interlayer insulating layer ILD2 may include an inorganic material including silicon oxide (SixOy) and silicon nitride (SixNy). However, the disclosure is not limited thereto.

The fourth interlayer conductive layer ICL4 may be disposed on the second interlayer insulating layer ILD2. The fourth interlayer conductive layer ICL4 may include a first fourth interlayer conductive layer ICL4-1 disposed in the polysilicon semiconductor area POA and a second fourth interlayer conductive layer ICL4-2 disposed in the oxide semiconductor area OXA. The fourth interlayer conductive layer ICL4 may include various conductive materials.

At least a portion of the first fourth interlayer conductive layer ICL4-1 may form the first transistor electrode TE1. The first transistor electrode TE1 may be a source electrode and/or a drain electrode for the first transistor TR1. The first transistor electrode TE1 may be electrically connected to the first active layer ACT1 through the intermediate conductive structure MCS.

At least a portion of the second fourth interlayer conductive layer ICL4-2 may form a second transistor electrode TE2. The second transistor electrode TE2 may be a source electrode and/or a drain electrode for the second transistor TR2. The second transistor electrode TE2 may be electrically connected to the first active layer ACT1 through a contact member provided through insulating layers (for example, the third gate insulating layer GI3 and the second interlayer insulating layer ILD2) between the second transistor electrode TE2 and the second active layer ACT2.

According to an embodiment, the first active layer ACT1, the first lower gate conductive layer BGAT1, the first upper gate conductive layer UGAT1, and the first transistor electrodes TE1 may form the first transistor TR1. The second active layer ACT2, the second lower gate conductive layer BGAT2, the second upper gate conductive layer UGAT2, and the second transistor electrodes TE2 may form the second transistor TR2.

The first fourth interlayer conductive layer ICL4-1 and the second fourth interlayer conductive layer ICL4-2 may be patterned in a same process, may be disposed in a same layer, and may include a same conductive material.

According to an embodiment, the fourth interlayer conductive layer ICL4 may include a material different from that of the third interlayer conductive layer ICL3. For example, the fourth interlayer conductive layer ICL4 may include a multilayer structure including aluminum, and the third interlayer conductive layer ICL3 may include a multilayer structure including molybdenum.

The first via layer VIA1 may cover the fourth interlayer conductive layer ICL4 and may be disposed on the second interlayer insulating layer ILD2. The first via layer VIA1 may be a planarization layer and may be a layer where at least one of contact members electrically connecting the first transistor TR1 and the anode electrode AE is formed. The first via layer VIA1 may include an organic material such as polyimide. However, the disclosure is not limited thereto.

The fifth interlayer conductive layer ICL5 may be disposed on the first via layer VIA1. At least a portion of the fifth interlayer conductive layer ICL5 may be disposed in the polysilicon semiconductor area POA. The fifth interlayer conductive layer ICL5 may include various conductive materials.

At least a portion of the fifth interlayer conductive layer ICL5 may function as a bridge for electrically connecting the first transistor electrode TE1 and the anode electrode AE. At least a portion of the fifth interlayer conductive layer ICL5 may be electrically connected to the first transistor electrode TE1 through a contact member provided through the first via layer VIA1.

The second via layer VIA2 may cover the fifth interlayer conductive layer ICL5 and may be disposed on the first via layer VIA1. The second via layer VIA2 may be a planarization layer and may be a layer where at least one of contact members electrically connecting the first transistor TR1 and the anode electrode AE to each other is formed. The second via layer VIA2 may include an organic material such as polyimide. However, the disclosure is not limited thereto.

The light emitting element layer LEL is disposed on the pixel circuit layer PCL and includes the light emitting element LD. The light emitting element layer LEL may further include a pixel defining layer PDL and an encapsulation layer TFE.

The light emitting element LD may include an anode electrode AE, an emission structure EL, and a cathode electrode CE. According to an embodiment, the emission structure EL may be disposed in an area defined by the pixel defining layer PDL. The pixel defining layer PDL may be adjacent to a periphery of the emission structure EL. A surface of the emission structure EL may be electrically connected to the anode electrode AE, and another surface of the emission structure EL may be electrically connected to the cathode electrode CE. The anode electrode AE and the cathode electrode CE may include at least one selected from various conductive materials.

The emission structure EL may include a plurality of layers. In an embodiment, for example, the emission structure EL may include a plurality of emission structures including a hole transport unit, a light emitting layer (or a light generation layer), and an electron transport unit. Each of the layers forming the emission structure may include an organic material, and according to an embodiment, the emission structure EL may further include a metal-containing compound, an inorganic material such as a quantum dot, or the like.

The hole transport unit may include a multilayer structure having a plurality of layers respectively including different materials. In an embodiment, for example, the hole transport unit may include a hole injection layer and a hole transport layer, and according to an embodiment, the hole transport unit may further include a light emitting auxiliary layer and an electron blocking layer.

The light emitting layer may include a material that may emit light of a color. The light emitting layer may include a host and a dopant. The host of the light emitting layer may be a light emitting material that may capture carriers (electron and hole) for light generation, and may induce an exciton to be efficiently generated. The dopant may include a phosphorescent dopant or a fluorescent dopant. According to an embodiment, a material of the dopant is not particularly limited. According to an embodiment, the dopant may include an organic material, and may include a metal complex, or the like.

The electron transport unit may include a multilayer structure having a plurality of layers respectively including different materials. The electron transport unit may include an electron injection layer and an electron transport layer, and according to an embodiment, the electron transport unit may further include an electron buffer layer, a hole blocking layer, and the like.

The pixel definition layer PDL may be disposed on the pixel circuit layer PCL to define a position where the emission structure EL is arranged. The pixel defining layer PDL may include an organic material or an inorganic material. In an embodiment, for example, the pixel defining layer PDL may include a plurality of layers each including an inorganic material. However, the disclosure is not limited thereto.

The encapsulation layer TFE may be disposed on the light emitting element LD (for example, the cathode electrode CE). The encapsulation layer TFE may cover a step generated by (or uneven structures formed by) the light emitting element LD and the pixel defining layer PDL. The encapsulation layer TFE may include a plurality of insulating layers covering the light emitting element LD. According to an embodiment, the encapsulation layer TFE may include an inorganic layer and an organic layer. For example, the encapsulation layer TFE may have a structure in which a first inorganic layer/an organic layer/a second inorganic layer are sequentially disposed. However, the disclosure is not limited thereto. According to an embodiment, the encapsulation layer TFE may be a thin film encapsulation layer.

Next, with reference to FIG. 4, another embodiment of the display device DD will be described. In FIG. 4, the same or like elements as those described above are labeled with the same or like reference characters as used above, and any repetitive detailed description thereof will hereinafter be omitted or simplified.

The display device DD shown in FIG. 4 is substantially the same as the display device DD show in FIG. 3, except that the first transistor electrodes TE1 are electrically connected directly to the first active layer ACT1 without via the intermediate conductive structure MCS.

In such an embodiment, the first transistor electrodes TE1 may be electrically connected to the first active layer ACT1 through a contact member provided through insulating layers (for example, the first gate insulating layer GI1, the second gate insulating layer GI2, the first interlayer insulating layer ILD1, the third gate insulating layer GI3, and the second interlayer insulating layer ILD2) between the first active layer ACT1 and the first transistor electrodes TE1. Here, the contact member may include a same conductive material as the first transistor electrodes TE1.

The intermediate conductive structure MCS may overlap the first upper gate conductive layer UGAT1 in a plan view or when viewed in the thickness direction of the base layer BSL. The intermediate conductive structure MCS may be electrically connected to the first upper gate conductive layer UGAT1. In an embodiment, for example, the intermediate conductive structure MCS may be electrically connected to the first upper gate conductive layer UGAT1 through the contact structure COP provided through insulating layers (for example, the second gate insulating layer GI2, the first interlayer insulating ILD1, and the third gate insulating layer GI3) between the intermediate conductive structure MCS and the first upper gate conductive layer UGAT1. In an embodiment, at least a portion of the contact structure COP may be surrounded by an additional gate conductive layer AGAT.

Next, with reference to FIG. 5, another embodiment of the display device DD will be described. In FIG. 5, the same or like elements as those described above are labeled with the same or like reference characters as used above, and any repetitive detailed description thereof will hereinafter be omitted or simplified.

The display device DD shown in FIG. 5 is substantially the same as the display device DD shown in FIG. 3, except that a portion of the intermediate conductive structure MCS is electrically connected to the first upper gate conductive layer UGAT1.

According to an embodiment, a portion of the intermediate conductive structure MCS may have a structural characteristic of the intermediate conductive structure MCS shown in FIG. 3, and another portion of the intermediate conductive structure MCS may have a structural characteristic of the intermediate conductive structure MCS shown in FIG. 4.

For example, in an embodiment, the first transistor electrodes TE1 may be electrically connected to the first active layer ACT1 through the intermediate conductive structure MCS and the contact structure COP. In an embodiment, a portion of the intermediate conductive structure MCS may be electrically connected to the first upper gate conductive layer UGAT1.

In an embodiment, a portion of the intermediate conductive structure MCS may overlap the first upper gate conductive layer UGAT1 in a plan view or when viewed in the thickness direction of the base layer BSL. A portion of the intermediate conductive structure MCS may be electrically connected to the first upper gate conductive layer UGAT1. In an embodiment, for example, a portion of the intermediate conductive structure MCS may be electrically connected to the first upper gate conductive layer UGAT1 through the contact structure COP provided through insulating layers (for example, the second gate insulating layer GI2, the first interlayer insulating layer ILD1, and the third gate insulating layer GI3) between the intermediate conductive structure MCS and the first upper gate conductive layer UGAT1. In an embodiment, at least a portion of the contact structure COP for a portion of the intermediate conductive structure MCS may be surrounded by the additional gate conductive layer AGAT.

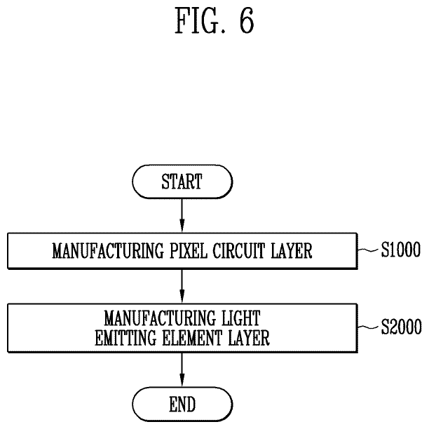

Hereinafter, a method of manufacturing a display device DD according to an embodiment will be described with reference to FIGS. 6 to 29. In FIGS. 6 to 29, the same or like elements as those described above are labeled with the same or like reference characters as used above, and any repetitive detailed description thereof will hereinafter be omitted or simplified.

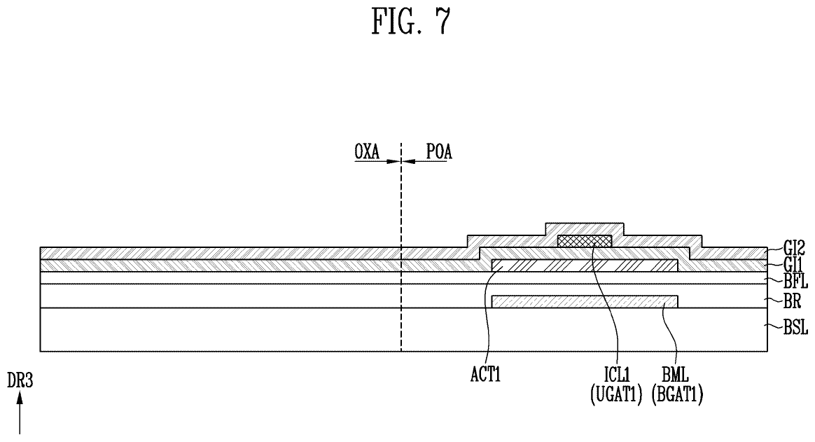

FIG. 6 is a schematic flowchart illustrating a manufacturing method of a display device according to an embodiment. FIGS. 7 to 29 are schematic cross-sectional views illustrating processes of a method of manufacturing a display device according to an embodiment. FIGS. 7 to 19 show processes in which layers of the pixel circuit layer PCL and the light emitting element layer LEL are formed in a manufacturing process of the display device DD.

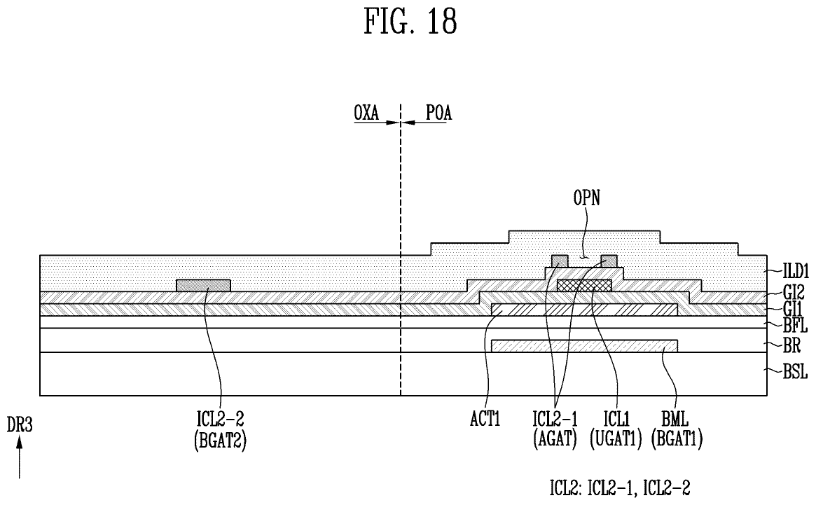

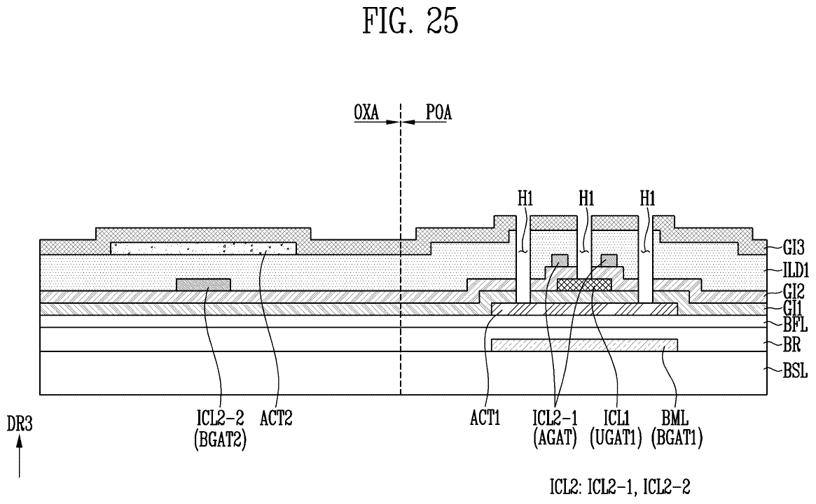

FIGS. 7 to 17 are shown based on the cross-sectional structure described above with reference to FIG. 3. FIGS. 18 to 24 are shown based on the cross-sectional structure described above with reference to FIG. 4. FIGS. 25 to 29 are shown based on the cross-sectional structure described above with reference to FIG. 5.

First, with reference to FIGS. 6 to 17, an embodiment of a method of manufacturing the display device DD shown in FIG. 3 will be described.

Referring to FIG. 6, a method of manufacturing a display device DD according to an embodiment may include manufacturing (e.g., forming or providing) a pixel circuit layer (S1000) and manufacturing a light emitting element layer (S2000).

Referring to FIG. 7, the lower conductive layer BML, the barrier layer BR, the buffer layer BFL, the first active layer ACT1, the first gate insulating layer GI1, and the second gate insulating layer GI2 may be formed (for example, patterned, i.e., formed in a patterned shape) on the base layer BSL.

According to an embodiment, the conductive layer or the insulating layer on the base layer BSL may be formed based on a conventional process for manufacturing a semiconductor device known in the art. In an embodiment, for example, the conductive layer or the insulating layer on the base layer BSL may be formed by a photolithography process, etched by one of various methods (wet etching, dry etching, or the like), or deposited by one of various methods (sputtering, a chemical vapor deposition method, or the like). The disclosure is not necessarily limited to a particular example.

In this process, at least a portion of the lower conductive layer BML may be patterned in a way such that the first lower gate conductive layer BGAT1 is formed in the polysilicon semiconductor area POA, the first active layer ACT1 may be patterned, and at least a portion of the first interlayer conductive layer ICL1 may be patterned in a way such that the first upper gate conductive layer UGAT1 is formed.

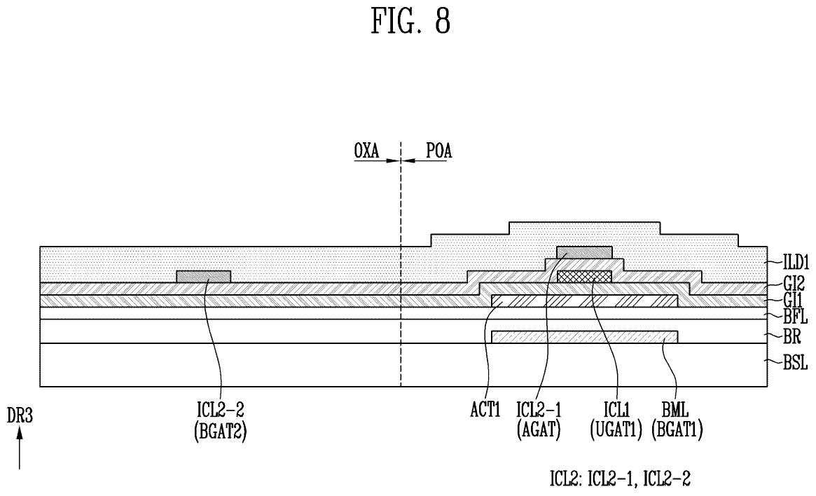

Referring to FIG. 8, the first second interlayer conductive layer ICL2-1 may be patterned on the second gate insulating layer GI2 in the polysilicon semiconductor area POA to form the additional gate conductive layer AGAT, the second second interlayer conductive layer ICL2-2 may be patterned on the second gate insulating layer GI2 in the oxide semiconductor area OXA to form the second lower gate conductive layer BGAT2, and the first interlayer insulating layer ILD1 covering the second interlayer conductive layers ICL2 may be formed.

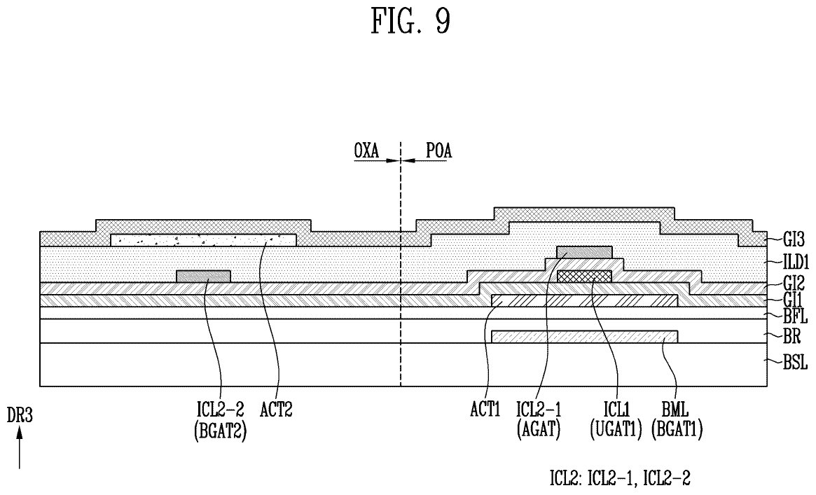

Referring to FIG. 9, the second active layer ACT2 may be patterned on the first interlayer insulating layer ILD1 in the oxide semiconductor area OXA, and the third gate insulating layer GI3 covering the second active layer ACT2 may be formed.

Referring to FIG. 10, at least a portion of insulating layers on the first active layer ACT1 may be etched in the polysilicon semiconductor area POA, and the first hole H1 may be formed thereby.

In this process, the first hole H1 may expose a portion of the first active layer ACT1. In an embodiment, for example, at least a portion of the first gate insulating layer GI1, the second gate insulating layer GI2, the first interlayer insulating layer ILD1, and the third gate insulating layer GI3 on the first active layer ACT1 may be removed.

According to an embodiment, a dry etching process may be performed to form the first hole H1. However, the disclosure is not limited thereto.

In this process, the second active layer ACT2 may still be covered by the third gate insulating layer GI3.

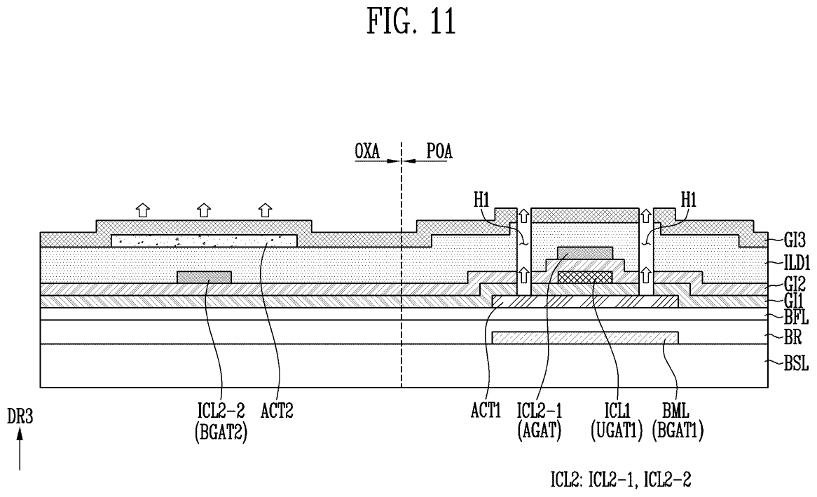

Referring to FIG. 11, an annealing process may be performed.

In this process, the annealing process may be performed using at least one selected from various methods. In an embodiment, for example, in the annealing process, a high temperature heating method using a furnace, rapid thermal annealing (RTA), which is a rapid heat treatment method, or the like may be used. However, the disclosure is not limited to a specific example.

The annealing process may substantially improve an ion injection characteristic for the exposed first active layer ACT1 and effectively prevent damage to the first active layer ACT1.

The annealing process may cause hydrogen combined to a dangling bond in a polysilicon material forming the first active layer ACT1 to be released, and thus a defect formation in the first active layer ACT1 may be promoted. Therefore, an element characteristic of the first active layer ACT1 may be controlled.

According to an embodiment, when the annealing process on the first active layer ACT1 is performed, since the first active layer ACT1 may be exposed by the first hole H1, hydrogen may be smoothly released to an outside from the first active layer ACT1.

In this process, the second active layer ACT2 may be covered only by the third gate insulating layer GI3, and thus hydrogen may be smoothly released to an outside from the second active layer ACT2. In an embodiment, for example, the third gate insulating layer GI3 may include silicon oxide (SixOy) and may not include silicon nitride (SixNy). That is, in such an embodiment, in a state in which the second active layer ACT2 is covered by an insulating layer including silicon oxide (SixOy), the above-described annealing process may be performed, and hydrogen may be smoothly released to the outside. Experimentally, when hydrogen is applied excessive to the second active layer ACT2, since the second active layer ACT2 includes an oxide semiconductor, a risk that an element characteristic such as a threshold voltage of the second active layer ACT2 is changed may occur. According to an embodiment, an environment in which the second active layer ACT2 may smoothly release hydrogen is provided when the annealing process is performed, such that the above-described risk may be reduced, thereby considering reliability for an electrical signal in the display device DD.

In addition, according to an embodiment, the first hole H1, which may function as a path for releasing hydrogen, may be a structure for forming the contact structure COP in a subsequent process. That is, since the first hole H1 may be manufactured in conjunction with an etching process for forming the first transistor TR1, the above-described technical feature may be implemented without using an additional mask, and a technical effect in which a process is simplified may be provided.

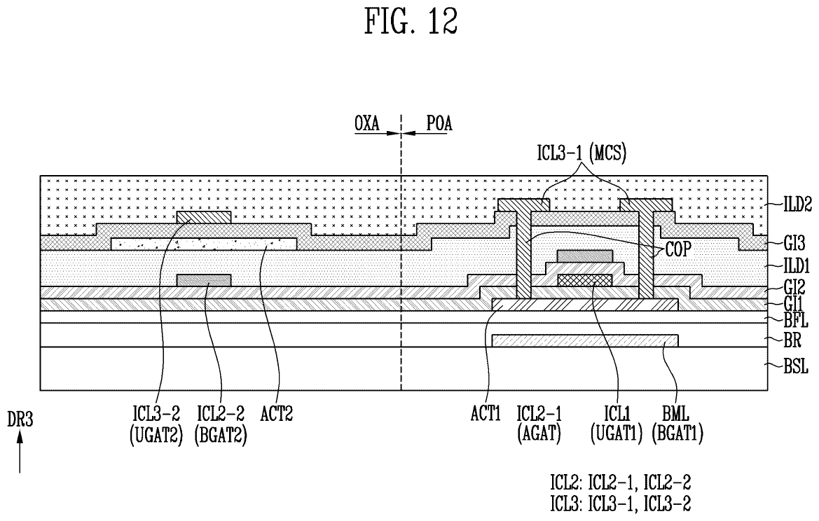

Referring to FIG. 12, the first third interlayer conductive layer ICL3-1 may be patterned on the third gate insulating layer GI3 in the polysilicon semiconductor area POA to form the intermediate conductive structure MCS, the second third interlayer conductive layer ICL3-2 may be patterned on the third gate insulating layer GI3 in the oxide semiconductor area OXA to form the second upper gate conductive layer UGAT2, and the second interlayer insulating layer ILD2 covering the third interlayer conductive layer ICL3 may be formed. In addition, when the third interlayer conductive layer ICL3 is formed, at least a portion of a conductive material may be provided in the first hole H1 such that the contact structure COP may be formed.

In an embodiment, the second interlayer insulating layer ILD2 may include silicon nitride (SixNy). In such an embodiment, the above-described annealing process may be performed before the second interlayer insulating layer ILD2 including silicon nitride (SixNy) is formed, and thus hydrogen may be thoroughly released from the second active layer ACT2.

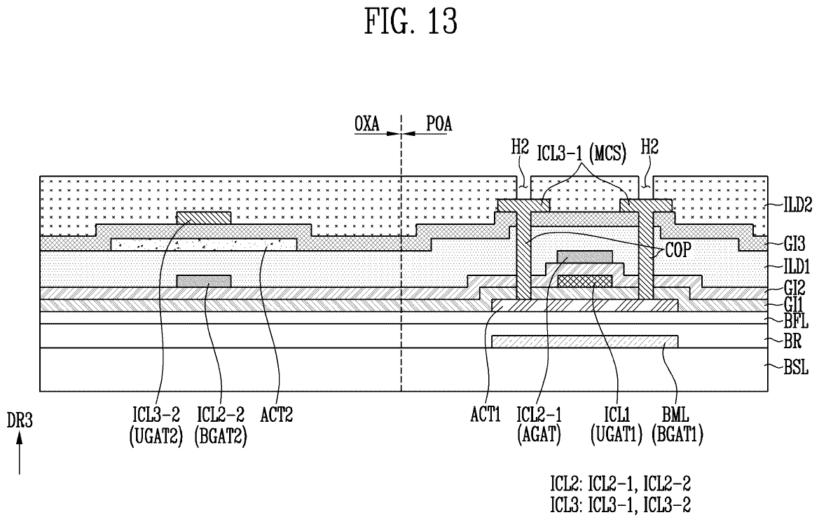

Referring to FIG. 13, at least a portion of insulating layers on the intermediate conductive structure MCS may be etched in the polysilicon semiconductor area POA, such that a second hole H2 may be formed.

In this process, the second hole H2 may expose at least a portion of the intermediate conductive structure MCS. In an embodiment, for example, at least a portion of the second interlayer insulating layer ILD2 on the intermediate conductive structure MCS may be removed.

According to an embodiment, for example, a dry etching process may be performed to form the second hole H2. However, the disclosure is not limited thereto.

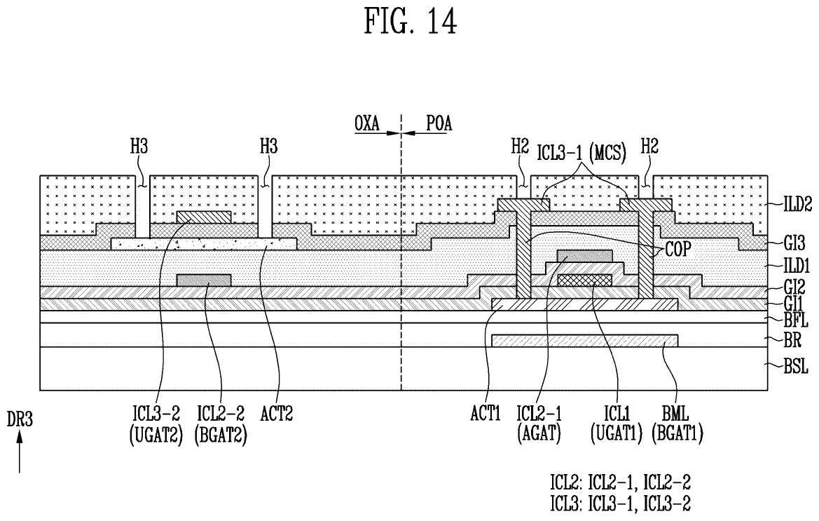

Referring to FIG. 14, at least a portion of insulating layers on the second active layer ACT2 may be etched in the oxide semiconductor area OXA, such that a third hole H3 may be formed.

In this process, the third hole H3 may expose at least a portion of the second active layer ACT2. In an embodiment, for example, at least a portion of the second interlayer insulating layer ILD2 on the second active layer ACT2 may be removed.

According to an embodiment, for example, a dry etching process may be performed to form the third hole H3. However, the disclosure is not limited thereto.

In such an embodiment, a sequential relationship between forming the second hole H2 and forming the third hole H3 is not particularly limited. In an embodiment, for example, forming the second hole H2 and forming the third hole H3 may be performed simultaneously, forming the third hole H3 may be performed before forming the second hole H2, or forming the second hole H2 may be performed before forming the third hole H3.

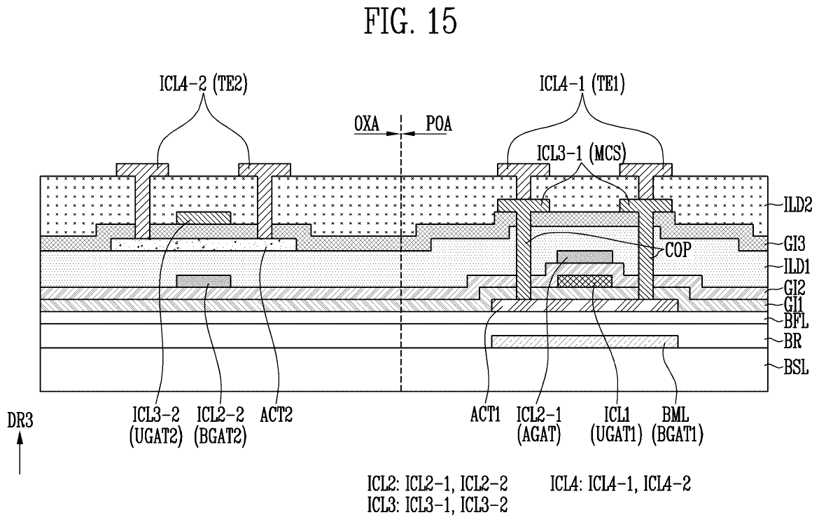

Referring to FIG. 15, the first fourth interlayer conductive layer ICL4-1 may be patterned on the second interlayer insulating layer ILD2 in the polysilicon semiconductor area POA to form the first transistor electrode TE1, and the second fourth interlayer conductive layer ICL4-2 may be patterned on the second interlayer insulating layer ILD2 in the oxide semiconductor area OXA to from the second transistor electrode TE2. Accordingly, the first transistor electrode TE1 may be electrically connected to the intermediate conductive structure MCS, the second transistor electrode TE2 may be formed, and the second transistor electrode TE2 may be connected to the second active layer ACT2.

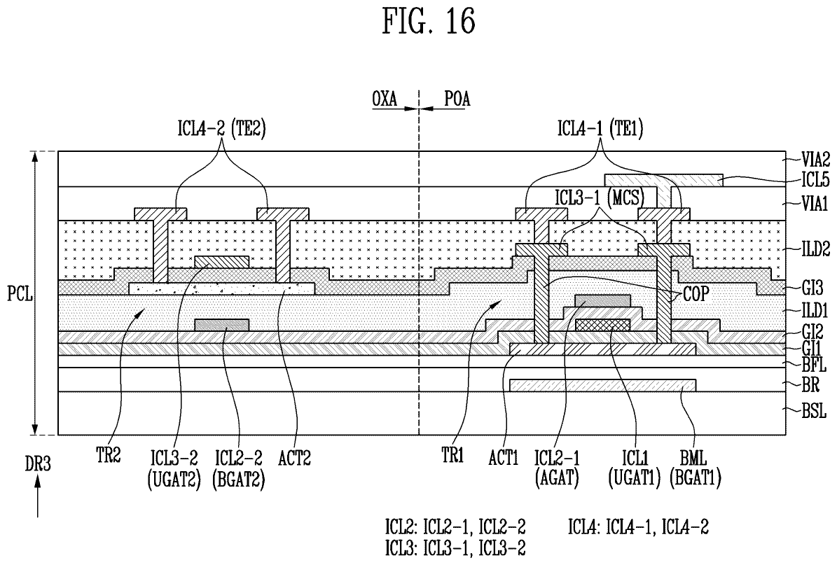

Referring to FIG. 16, the via layer VIA1 may be formed, after a contact hole is formed in the via layer VIA1, at least a portion of the fifth interlayer conductive layer ICL5 in the polysilicon semiconductor area POA may be patterned, and the second via layer VIA2 covering the fifth interlayer conductive layer ICL5 may be formed. Accordingly, the fifth interlayer conductive layer ICL5 may be electrically connected to the first transistor electrode TE1.

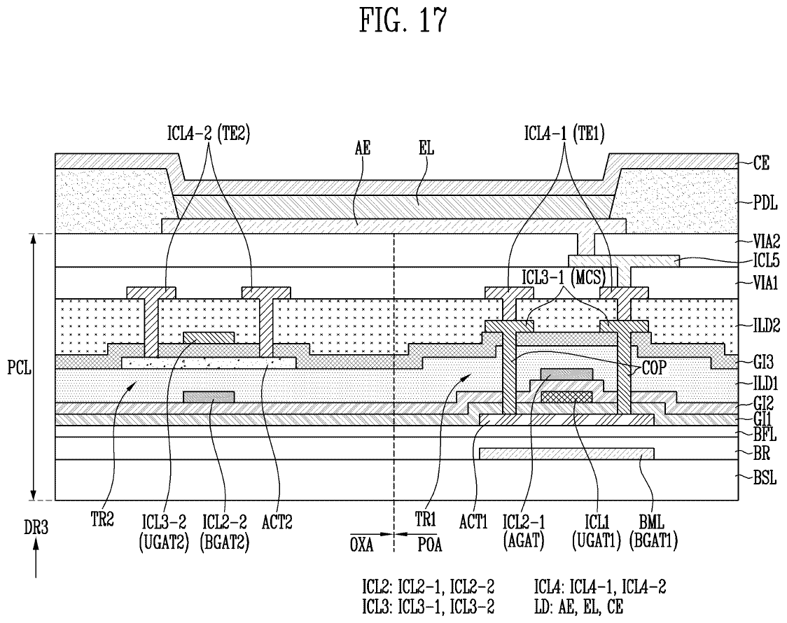

Referring to FIG. 17, after forming a contact hole in the second via layer VIA2, the anode electrode AE, the pixel defining layer PDL, the emission structure EL, and the cathode electrode CE may be patterned (for example, sequentially patterned). Accordingly, the light emitting element LD on the pixel circuit layer PCL may be formed. Thereafter, according to an embodiment, the encapsulation layer TFE or the like may be further formed on the light emitting element LD, and a display device DD according to an embodiment may be provided.

Next, with reference to FIG. 6 and FIGS. 18 to 24, an embodiment of a method of manufacturing the display device DD shown in FIG. 4 will be described. In FIGS. 18 to 24, the same or like elements as those described above are labeled with the same or like reference characters as used above, and any repetitive detailed description thereof will hereinafter be omitted or simplified.

In the method of manufacturing the display device DD according to such an embodiment, the process described above with reference to FIG. 7 may be performed identically.

Referring to FIG. 18, the first second interlayer conductive layer ICL2-1 may be patterned to form an opening OPN in the polysilicon semiconductor area POA. The opening OPN may correspond to an area for the contact structure COP to be formed through in a subsequent process.

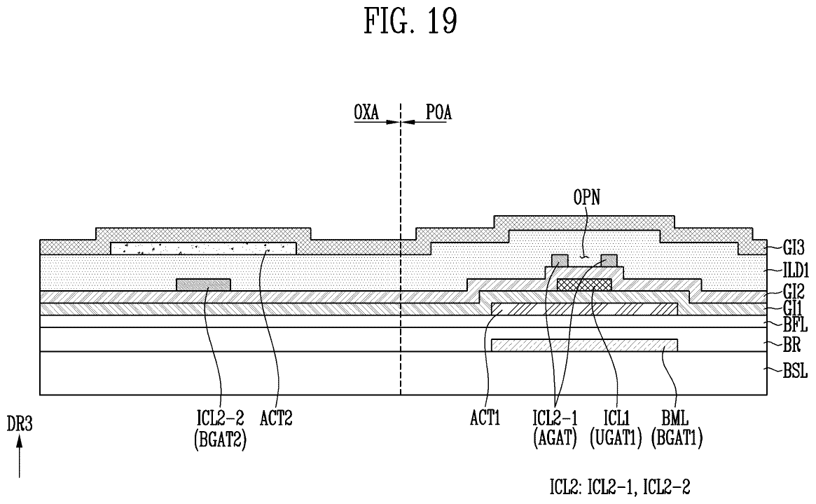

Referring to FIG. 19, the second active layer ACT2 may be patterned on the first interlayer insulating layer ILD1 in the oxide semiconductor area OXA, and the third gate insulating layer GI3 covering the second active layer ACT2 may be formed. In this process, the first second interlayer conductive layer ICL2-1 with the opening OPN may still be covered by the first interlayer insulating layer ILD1.

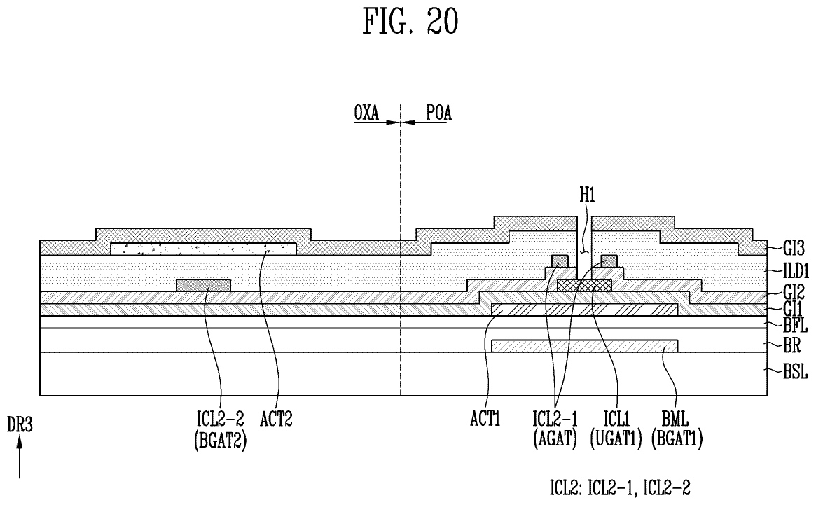

Referring to FIG. 20, at least a portion of insulating layers on the first upper gate conductive layer UGAT1 may be etched in the polysilicon semiconductor area POA, such that the first hole H1 may be formed.

In this process, the first hole H1 may expose a portion of the first upper gate conductive layer UGAT1. In an embodiment, for example, at least a portion of the second gate insulating layer GI2, the first interlayer insulating layer ILD1, and the third gate insulating layer GI3 on the first upper gate conductive layer UGAT1 may be removed.

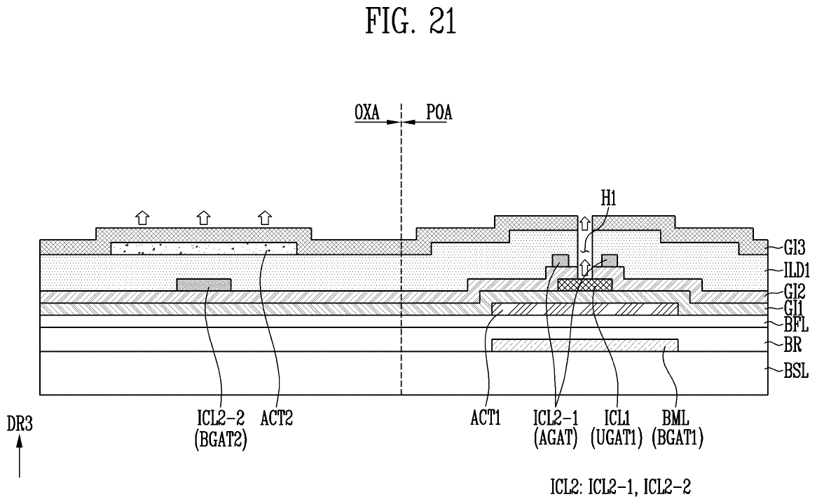

Referring to FIG. 21, an annealing process on the first active layer ACT1 may be performed.

In such an embodiment, as described above, the first hole H1 may form a path through which hydrogen may be released from the first active layer ACT1, and an annealing process may be performed in a state in which the second active layer ACT2 is covered only by the third gate insulating layer GI3. Accordingly, hydrogen may be thoroughly released to the outside from the first and second active layers ACT1 and ACT2.

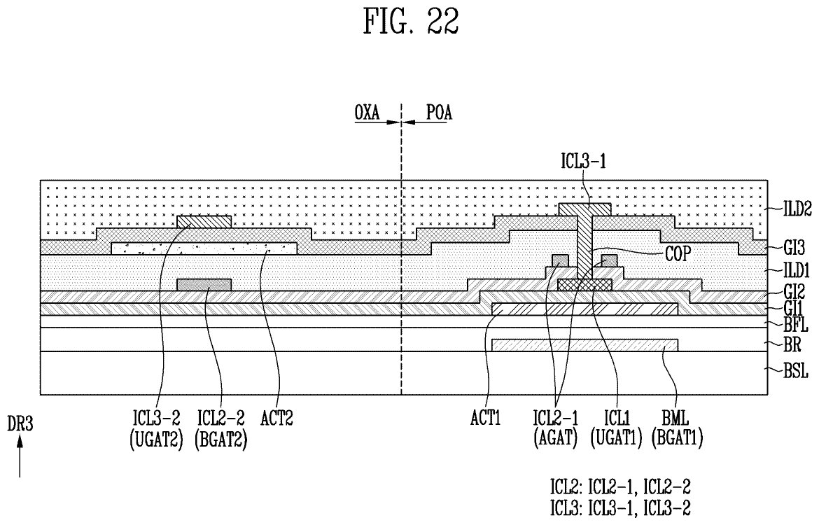

Referring to FIG. 22, the first third interlayer conductive layer ICL3-1 may be patterned on the third gate insulating layer GI3 in the polysilicon semiconductor area POA to form the intermediate conductive structure MCS, the second third interlayer conductive layer ICL3-2 may be patterned on the third gate insulating layer GI3 in the oxide semiconductor area OXA to form the second upper gate conductive layer UGAT2, and the second interlayer insulating layer ILD2 covering the third interlayer conductive layer ICL3 may be formed. Accordingly, the intermediate conductive structure MCS may be electrically connected to the first upper gate conductive layer UGAT1.

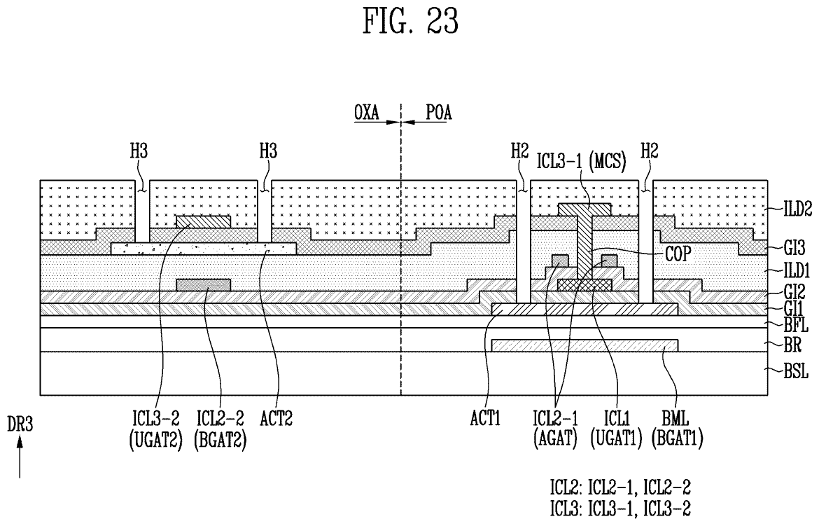

Referring to FIG. 23, at least a portion of insulating layers on each of the first and second active layers ACT1 and ACT2 may be dry etched, such that the second hole H2 exposing the first active layer ACT1 and the third hole H3 exposing the second active layer ACT2 may be formed.

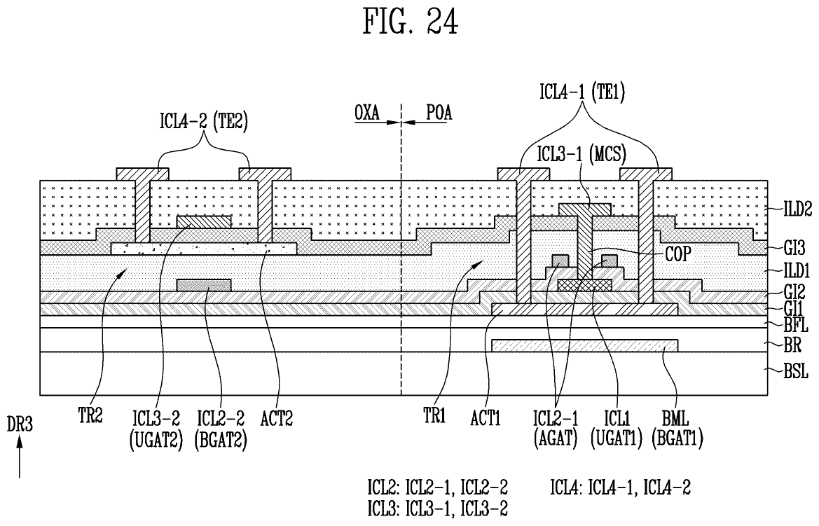

Referring to FIG. 24, the first fourth interlayer conductive layer ICL4-1 may be patterned on the second interlayer insulating layer ILD2 in the polysilicon semiconductor area POA to form the first transistor electrode TE1, and the second fourth interlayer conductive layer ICL4-2 may be patterned on the second interlayer insulating layer ILD2 in the oxide semiconductor area OXA to form the second transistor electrode TE2. In this process, the first transistor electrode TE1 may not be electrically connected to the intermediate conductive structure MCS, and may be electrically connected to the first active layer ACT1 without passing through the intermediate conductive structure MCS.

Thereafter, according to an embodiment, the first via layer VIA1, the fifth interlayer conductive layer ICL5, the second via layer VIA2, and the light emitting element layer LEL may be formed, and thus a display device DD according to an embodiment may be provided.

Next, with reference to FIG. 6 and FIGS. 25 to 29, an embodiment of a method of manufacturing the display device DD shown in FIG. 5 is described. In FIGS. 25 to 29, the same or like elements as those described above are labeled with the same or like reference characters as used above, and any repetitive detailed description thereof will hereinafter be omitted or simplified.

In the manufacturing method of the display device DD according to such an embodiment, the processes described above with reference to FIGS. 18 and 19 may be performed identically.

Referring to FIG. 25, at least a portion of insulating layers on the first active layer ACT1 and the first upper gate conductive layer UGAT1 may be etched in the polysilicon semiconductor area POA, such that the first hole H1 may be formed.

In this process, the first hole H1 may expose a portion of the first upper gate conductive layer UGAT1 and expose a portion of the first active layer ACT1. In an embodiment, for example, at least a portion of the second gate insulating layer GI2, the first interlayer insulating layer ILD1, and the third gate insulating layer GI3 on the first upper gate conductive layer UGAT1 may be removed, and at least a portion of the first gate insulating layer GI1, the second gate insulating layer GI2, the first interlayer insulating layer ILD1, and the third gate insulating layer GI3 on the first active layer ACT1 may be removed.

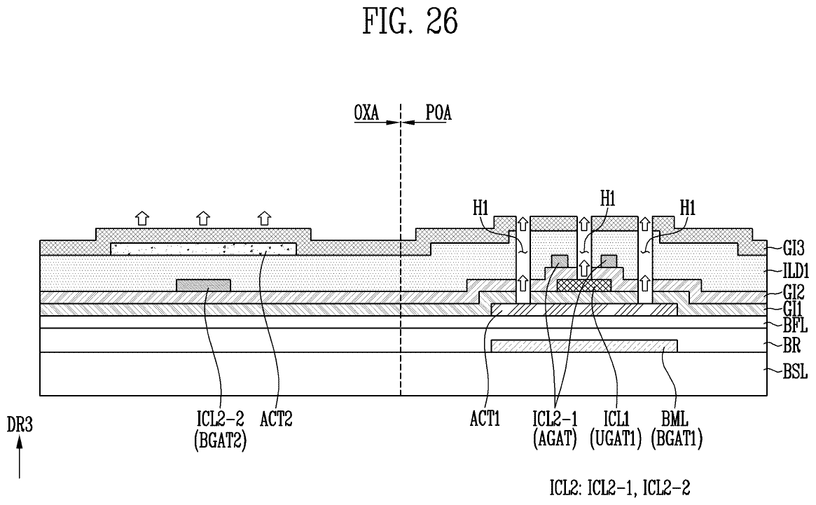

Referring to FIG. 26, an annealing process on the first active layer ACT1 may be performed.

In such an embodiment, as described above, the first hole H1 may form a path through which hydrogen may be released from the first active layer ACT1, and an annealing process may be performed in a state in which the second active layer ACT2 is covered only by the third gate insulating layer GI3. Accordingly, hydrogen may be released to the outside from the first and second active layers ACT1 and ACT2.

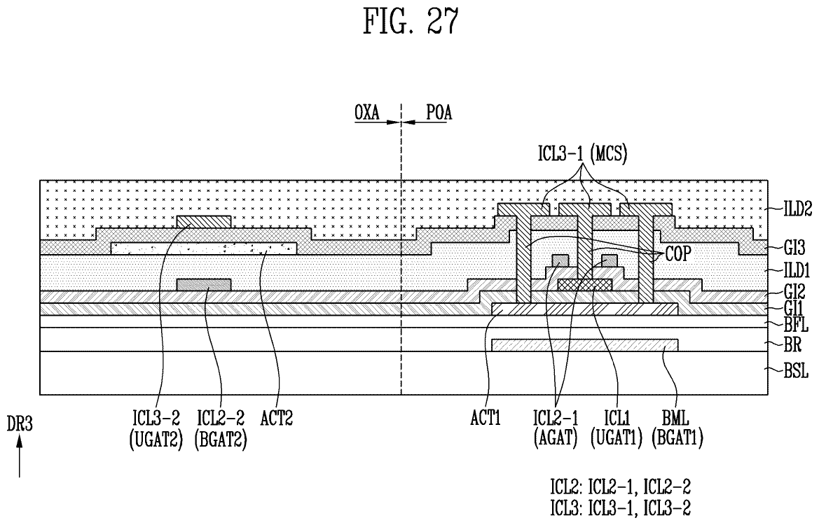

Referring to FIG. 27, the first third interlayer conductive layer ICL3-1 may be patterned on the third gate insulating layer GI3 in the polysilicon semiconductor area POA to form the intermediate conductive structure MCS, the second third interlayer conductive layer ICL3-2 may be patterned on the third gate insulating layer GI3 in the oxide semiconductor area OXA to form the second upper gate conductive layer UGAT2, and the second interlayer insulating layer ILD2 covering the third interlayer conductive layer ICL3 may be formed. Accordingly, a portion of the intermediate conductive structure MCS may be electrically connected to the first active layer ACT1, and another portion of the intermediate conductive structure MCS may be electrically connected to the first upper gate conductive layer UGAT1.

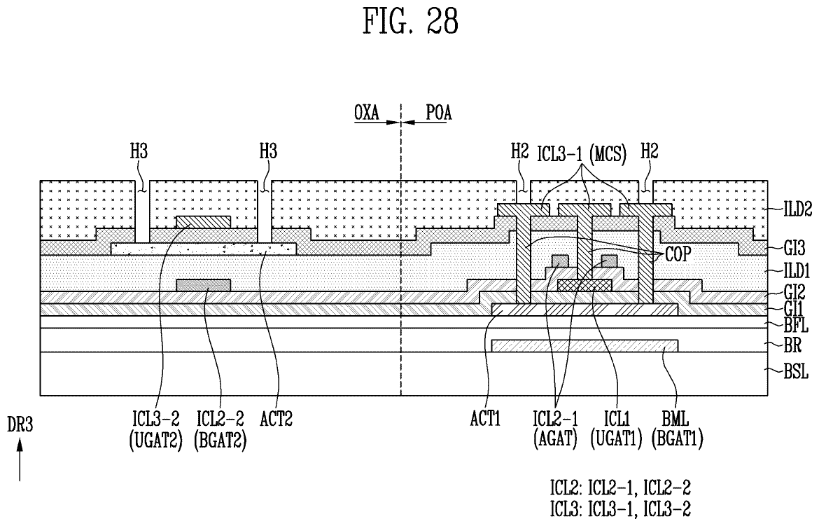

Referring to FIG. 28, at least a portion of insulating layers on each of the first and second active layers ACT1 and ACT2 may be dry etched, such that the second hole H2 exposing the first active layer ACT1 and the third hole H3 exposing the second active layer ACT2 may be formed. In this process, the second hole H2 may not expose a portion of the intermediate conductive structure MCS that overlaps the first upper gate conductive layer UGAT1.

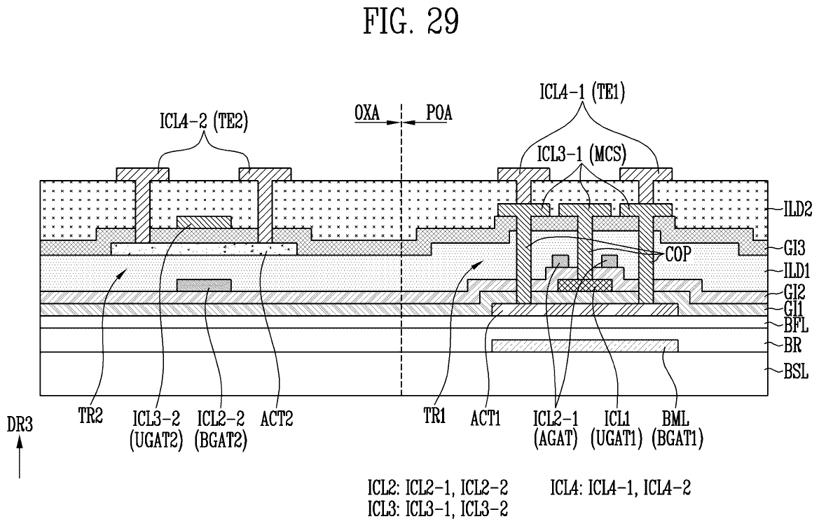

Referring to FIG. 29, the first fourth interlayer conductive layer ICL4-1 may be patterned on the second interlayer insulating layer ILD2 in the polysilicon semiconductor area POA to form the first transistor electrode TE1, and the second fourth interlayer conductive layer ICL4-2 may be patterned on the second interlayer insulating layer ILD2 in the oxide semiconductor area OXA. In this process, the first transistor electrode TE1 may be electrically connected to the first active layer ACT1 through the intermediate conductive structure MCS, and may not be electrically connected to a portion of the intermediate conductive structure MCS overlapping the first upper gate conductive layer UGAT1.

Thereafter, according to an embodiment, the first via layer VIA1, the fifth interlayer conductive layer ICL5, the second via layer VIA2, and the light emitting element layer LEL may be formed, and thus a display device DD according to an embodiment may be provided.

Hereinafter, an electronic device 1000 including the display device DD in accordance with an embodiment will be described.

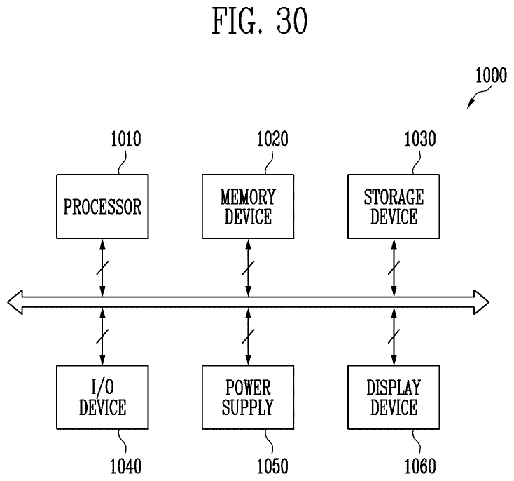

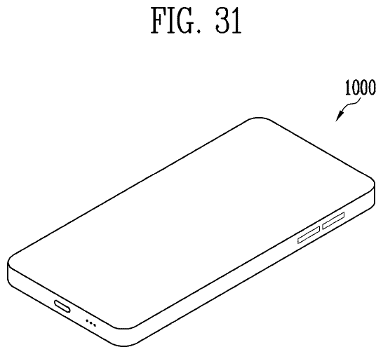

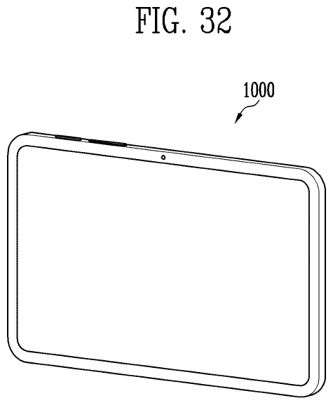

FIG. 30 is a schematic block diagram illustrating an electronic device 1000 including a display device in accordance with an embodiment. FIG. 31 is a schematic diagram illustrating an example where the electronic device 1000 of FIG. 30 is implemented as a smartphone. FIG. 32 is a schematic diagram illustrating an example where the electronic device 1000 of FIG. 30 is implemented as a tablet computer.

Referring to FIGS. 30 to 32, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 31, the electronic device 1000 may be a smartphone. In an embodiment, as illustrated in FIG. 32, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a pixel circuit layer including a base layer, a first transistor disposed on the base layer and a second transistor disposed on the base layer, wherein the first transistor includes a first active layer, a first upper gate conductive layer disposed on the first active layer, and an intermediate conductive structure disposed on the first active layer and further spaced apart from the base layer than the first upper gate conductive layer is, and the second transistor includes a second active layer and a second upper gate conductive layer disposed on the second active layer; and
a light emitting element disposed on the pixel circuit layer,
wherein the first active layer includes a polysilicon material and is disposed in a polysilicon semiconductor area,
the second active layer includes an oxide semiconductor and is disposed in an oxide semiconductor area, and
the intermediate conductive structure is disposed in a same layer as the second upper gate conductive layer and is electrically connected to at least one selected from the first active layer and the first upper gate conductive layer through a contact structure.

2. The display device of claim 1, wherein the first transistor includes a driving transistor,
the second transistor includes a switching transistor, and
the second active layer is further spaced apart from the base layer than the first active layer is.

3. The display device of claim 1, wherein the first active layer includes at least one selected from low-temperature polycrystalline silicon (LTPS), hybrid oxide polycrystalline silicon (HOP), and hybrid oxide low-temperature polycrystalline silicon (HOL), and
the second active layer includes at least one selected from indium gallium zinc oxide (IGZO) and indium tin gallium zinc oxide (ITGZO).

4. The display device of claim 1, wherein the first transistor further includes an additional gate conductive layer overlapping the first upper gate conductive layer in a plan view,
the second transistor further includes a lower gate conductive layer disposed between the second active layer and the base layer, and
the additional gate conductive layer and the lower gate conductive layer are disposed in a same layer as each other.

5. The display device of claim 1, wherein the first transistor further includes first transistor electrodes disposed on the intermediate conductive structure,
the second transistor further includes second transistor electrodes disposed in a same layer as the first transistor electrodes, and
the contact structure includes a conductive material different from a material of the first transistor electrodes.

6. The display device of claim 5, wherein the intermediate conductive structure electrically connects the first transistor electrodes and the first active layer to each other.

7. The display device of claim 1, wherein the intermediate conductive structure is electrically connected to the first upper gate conductive layer.

8. The display device of claim 1, wherein a portion of the intermediate conductive structure is electrically connected to the first active layer, and
another portion of the intermediate conductive structure is electrically connected to the first upper gate conductive layer.

9. A method of manufacturing a display device, the method comprising:
manufacturing a pixel circuit layer; and
manufacturing a light emitting element layer disposed on the pixel circuit layer,
wherein the manufacturing the pixel circuit layer comprises:
patterning a first active layer in a polysilicon semiconductor area on a base layer;
patterning a first upper gate conductive layer overlapping the first active layer;
patterning a second active layer in an oxide semiconductor area on the base layer;
forming a first hole exposing at least one selected from the first upper gate conductive layer and the first active layer;
performing an annealing process; and
patterning a second upper gate conductive layer and an intermediate conductive structure, after the performing the annealing process.

10. The method of claim 9, further comprising:
patterning an additional gate conductive layer overlapping the first upper gate conductive layer in the polysilicon semiconductor area and a lower gate conductive layer in the oxide semiconductor area,
wherein the patterning the second active layer comprises forming the second active layer to overlap the lower gate conductive layer.

11. The method of claim 9, wherein the performing the annealing process comprises releasing hydrogen from the first active layer and the second active layer.

12. The method of claim 11, further comprising:
forming a gate insulating layer covering the second active layer, after the patterning the second active layer,
wherein in the performing the annealing process, the gate insulating layer covers the second active layer,
the gate insulating layer includes silicon oxide (SixOy) and does not include silicon nitride (SixNy).

13. The method of claim 12, further comprising:
forming an interlayer insulating layer on the second upper gate conductive layer and the intermediate conductive structure,
wherein the interlayer insulating layer includes silicon nitride (SixNy).

14. The method of claim 13, further comprising:
forming a second hole exposing the intermediate conductive structure; and
forming a third hole exposing the second active layer.

15. The method of claim 14, further comprising:
patterning first transistor electrodes and second transistor electrodes,
wherein the first transistor electrodes are formed in the second hole and electrically connected to the intermediate conductive structure, and the second transistor electrodes are formed in the third hole and electrically connected to the second active layer.

16. The method of claim 15, wherein the first transistor electrodes and the intermediate conductive structure include different conductive materials.

17. The method of claim 9, wherein the forming the first hole comprises exposing the first upper gate conductive layer without exposing the first active layer.

18. The method of claim 17, wherein the patterning the first upper gate conductive layer comprises forming an opening through the first upper gate conductive layer, and
in the forming the first hole, the first hole passes through the opening.

19. The method of claim 9, wherein the forming the first hole comprises exposing the first active layer; and
exposing the first upper gate conductive layer.

20. The method of claim 19, wherein the patterning the intermediate conductive structure comprises:
electrically connecting a portion of the intermediate conductive structure to the first active layer; and
electrically connecting another portion of the intermediate conductive structure to the first upper gate conductive layer.

21. An electronic device, comprising:
a processor configured to provide input image data;
a display device configured to display an image based on the input image data, the display device including sub-pixel areas; and
a power supply configured to supply power to the display device,
wherein the display device comprises:
a pixel circuit layer including a base layer, a first transistor disposed on the base layer and a second transistor disposed on the base layer, wherein the first transistor includes a first active layer, a first upper gate conductive layer disposed on the first active layer, and an intermediate conductive structure disposed on the first active layer and further spaced apart from the base layer than the first upper gate conductive layer is, and the second transistor includes a second active layer and a second upper gate conductive layer disposed on the second active layer; and
a light emitting element disposed on the pixel circuit layer,
wherein the first active layer includes a polysilicon material and is disposed in a polysilicon semiconductor area,
the second active layer includes an oxide semiconductor and is disposed in an oxide semiconductor area, and
the intermediate conductive structure is disposed in a same layer as the second upper gate conductive layer and is electrically connected to at least one selected from the first active layer and the first upper gate conductive layer through a contact structure.
